(19) United States
(12) Patent Application Publication
(10) Pub. No.: US 2020/0049422 A1
(43) Pub. Date: Feb. 13, 2020

(54) VAPOR CHAMBER

(71) Applicant: Murata Manufacturing Co., Ltd., Nagaokakyo-shi (JP)

(72) Inventor: Osamu Chikagawa, Nagaokakyo-shi (JP)

(21) Appl. No.: 16/655,334

(22) Filed: Oct. 17, 2019

Related U.S. Application Data
(63) Continuation of application No. PCT/JP2017/017047, filed on Apr. 28, 2017.

(51) Int. Cl. F28D 15/04; G03F 7/20

(52) U.S. Cl. CPC F28D 15/046; G03F 7/70

(57) ABSTRACT

A vapor chamber that includes a housing, and working fluid that is sealed in the housing. The housing has a plurality of protrusions on at least one main surface inside the housing, the protrusions are composed of a columnar portion and a head portion, at least one lateral surface of the head portion faces a lateral surface of another head portion, and a first area of the head portion measured in a direction perpendicular to the main surface of the housing is larger than a second area of the columnar portion.

### CROSS REFERENCE TO RELATED APPLICATIONS

The present application is a continuation of International application No. PCT/JP2017/017047, filed Apr. 28, 2017, the entire contents of which is incorporated herein by reference.

### FIELD OF THE INVENTION

The present invention relates to a vapor chamber.

### BACKGROUND OF THE INVENTION

In recent years, the amount of heat generated has been increasing as integration and performance of elements has increased. Further, heat density has been increasing as products are reduced in size, and measures for heat dissipation have consequently become important. This situation is especially notable in the field of mobile terminals such as a smartphone and a tablet. A graphite sheet or the like is often used as a heat countermeasure member in recent years. However, since a heat transport amount of graphite sheets is not sufficient, alternative heat countermeasure members have been studied. Especially, studies in the use of a vapor chamber, which is a planar heat pipe, has progressed as a vapor chamber can very efficiently diffuse heat.

A vapor chamber is a plate-shaped hermetic container in which an appropriate amount of a volatile working fluid is sealed therein. The working fluid is vaporized by heat from a heat source, moves in a space, and then discharges the heat to return to a liquid state. The working fluid which has returned to the liquid state is transported to the vicinity of the heat source again by a capillary structure called a wick and is vaporized again. Through repetition of this process, a vapor chamber can autonomously operate without requiring external power and two-dimensionally diffuse heat at high speed by using vaporization of the working fluid and latent heat of condensation.

Patent Document 1 discloses a metallic porous body with a three-dimensional network structure which can be used as a wick of a vapor chamber. In an aluminum based porous body used as the metallic porous body of Patent Document 1, pores through which working fluid flows have a size of 30 to 4000 μm. A channel for working fluid is thus formed thin, allowing capillary force to efficiently act and improving transportation performance for working fluid of a wick.

Patent Document 1: Japanese Unexamined Patent Application Publication No. 2016-183390

### SUMMARY OF THE INVENTION

However, when a porous body as the one in Patent Document 1 is used as a wick, the working fluid can be three-dimensionally moved but the moving direction of the working fluid cannot be controlled. Further, if a channel is formed thin so as to enhance capillary forces, permeability is degraded and accordingly, transportation performance for the working fluid may be lowered. Furthermore, if a channel is formed wide to increase permeability, the capillary force is lowered and transportation performance for the working fluid may be lowered in a similar manner.

Therefore, an object of the present invention is to provide a vapor chamber that has a wick structure by which a moving direction of the working fluid can be controlled and which has excellent transportation performance for the working fluid.

In order to solve the above-described problems, a vapor chamber according to the present invention includes a housing, and a working fluid that is sealed in the housing. The housing is provided with a plurality of protrusions on at least one main surface inside the housing, each of the protrusions is composed of a columnar portion and a head portion, at least one lateral surface of the head portion faces a lateral surface of another head portion, and a first area of the head portion measured in a direction perpendicular to a main surface of the housing is larger than a second area of the columnar portion.

In the vapor chamber according to an aspect, the head portion has a rectangular shape when viewed from a direction perpendicular to a main surface of the housing.

In the vapor chamber according to another aspect, the head portion has a width of 100 μm to 500 μm inclusive.

In the vapor chamber according to still another aspect, a distance between a head portion of the protrusion and a head portion of the adjacent protrusion is from 10 μm to 50 μm inclusive.

In the vapor chamber according to yet another aspect, a distance between a head portion of the protrusion and a head portion of the adjacent protrusion is constant.

In the vapor chamber according to yet another aspect, the columnar portion has a height of 1 μm to 100 μm inclusive.

In the vapor chamber according to yet another aspect, the protrusion is covered with metal.

In the vapor chamber according to yet another aspect, the metal is Cu.

The vapor chamber according to yet another aspect can be manufactured by a manufacturing method including: forming a first-layer photoresist on a main surface inside a housing; exposing the first-layer photoresist in a pattern corresponding to a columnar portion; forming a second-layer photoresist on the exposed first-layer photoresist; exposing the second-layer photoresist in a pattern corresponding to a head portion; and developing the first-layer photoresist and the second-layer photoresist to obtain a resist pattern corresponding to a protrusion.

According to the present invention, a vapor chamber that has a wick structure by which a moving direction of working fluid can be controlled and which has excellent transportation performance for working fluid is provided.

### BRIEF DESCRIPTION OF THE DRAWINGS

FIG. 1 is a sectional view of a vapor chamber according to an embodiment of the present invention.

FIG. 2 is a perspective view illustrating a plurality of protrusions on a main surface inside the vapor chamber according to the embodiment of the present invention.

FIG. 3 is a perspective view illustrating a plurality of protrusions on the main surface inside the vapor chamber according to the embodiment of the present invention.

FIG. 4A is a diagram illustrating a manufacturing method for a plurality of protrusions of the vapor chamber according to the embodiment of the present invention.

FIG. 4B is a diagram illustrating the manufacturing method for a plurality of protrusions of the vapor chamber according to the embodiment of the present invention.

FIG. 4C is a diagram illustrating the manufacturing method for a plurality of protrusions of the vapor chamber according to the embodiment of the present invention.

FIG. 4D is a diagram illustrating the manufacturing method for a plurality of protrusions of the vapor chamber according to the embodiment of the present invention.

FIG. 4E is a diagram illustrating the manufacturing method for a plurality of protrusions of the vapor chamber according to the embodiment of the present invention.

### DETAILED DESCRIPTION OF THE PREFERRED EMBODIMENTS

The present invention is further detailed below with reference to the accompanying drawings.

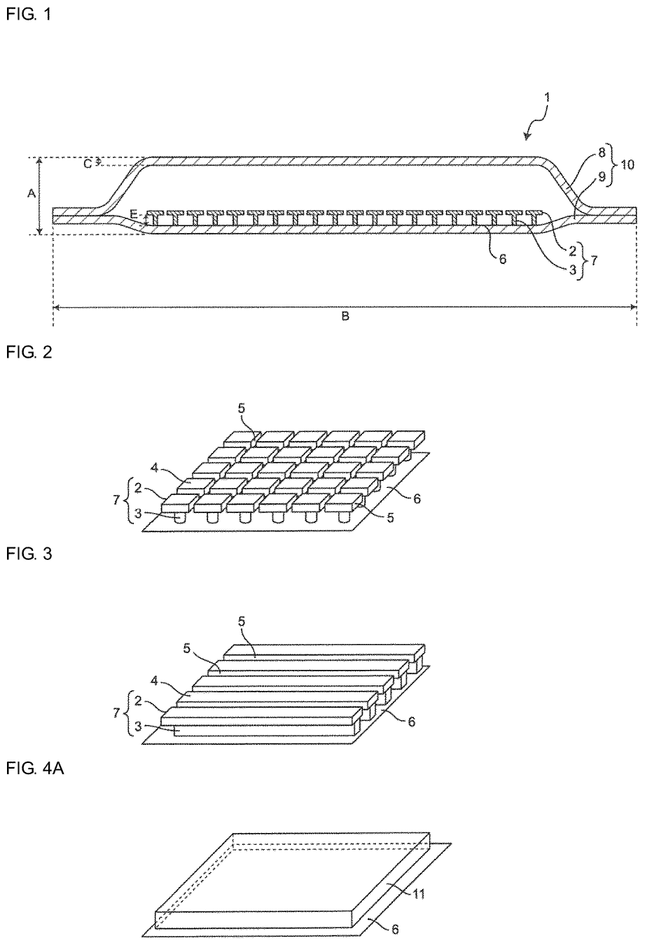

FIG. 1 is a sectional view of a vapor chamber 1 according to the present invention, and FIG. 2 is a perspective view illustrating a plurality of protrusions 7 on a main surface 6 inside the vapor chamber 1 according to the present invention. The vapor chamber 1 according to the present invention includes a housing 10, and the housing 10 has the plurality of protrusions 7 on at least one main surface inside the housing 10. The protrusion 7 is composed of a columnar portion 3 and a head portion 2 and at least one lateral surface 5 of the head portion 2 faces a lateral surface 5 of another head portion 2. A first area of the head portion 2 measured in a direction perpendicular to the main surface 6 of the housing 10 is larger than a second area of the columnar portion 3 in the direction perpendicular to the main surface 6 of the housing 10. Though not illustrated in FIG. 1, the vapor chamber 1 according to the present invention further includes a working fluid sealed in the housing 10.

In the vapor chamber 1 according to the present invention, adjacent columnar portions 3 are separated from each other as illustrated in FIG. 1 and the working fluid can be held in a space defied by wall surfaces of the columnar portions 3 and bottom surfaces of the head portions 2. The bottom surface of the head portion 2 is a surface on which the columnar portion 3 exists and is a lower surface, in the drawing, of the head portion 2 in FIG. 1 and FIG. 2. Further, lateral surfaces 5 of adjacent head portions 2 are separated from each other and a distance between the lateral surfaces 5 of adjacent head portions 2 is smaller than a distance between adjacent columnar portions 3, as illustrated in FIG. 2. A gap between lateral surfaces 5 of adjacent head portions 2 is narrow in width compared to a space (also referred to merely as a “space among columnar portions 3” below) defined by the wall surfaces of the columnar portions 3, the main surface 6 of the housing 10, and the bottom surfaces of the head portions 2 (a surface obtained by connecting bottom surfaces of adjacent head portions, between head portions), the space in which the working fluid is held, and a larger capillary force acts in the gap. Therefore, the capillary force in the gap efficiently promotes the working fluid to move in a direction substantially parallel to the width direction of the lateral surface 5 of the head portion 2 of the protrusion 7, in the vapor chamber 1 according to the present invention. Here, on the lateral surface of the head portion, the direction parallel to the main surface of the housing is referred to as the width direction and the perpendicular direction is referred to as the height direction. Since the gap between adjacent lateral surfaces 5 communicates with the space among columnar portions 3, working fluid moving through the gap between the lateral surfaces 5 and working fluid held in the space among the columnar portions 3 form mutually identical liquid phases. Therefore, the working fluid held in the space among the columnar portions 3 moves in the same direction along with movement of the working fluid in the gap between the lateral surfaces 5. In the vapor chamber 1 according to the present invention, there are few obstacles disturbing the flow of the working fluid in the space among the columnar portions 3, so that permeability representing a degree of passing easiness of the working fluid is significantly excellent compared to porous materials of the related art. The vapor chamber 1 according to the present invention has gaps among the lateral surfaces 5 for enhancing the capillary force acting on the working fluid and a space among the columnar portions 3 which is integrated with the gaps and functions as a channel of the working fluid, so that the vapor chamber 1 has very excellent transportation performance for the working fluid.

Further, the moving direction of the working fluid is the direction parallel to the width direction of the lateral surface 5 in the present invention. Therefore, the moving direction of the working fluid can be easily controlled by setting the width direction of the lateral surface 5 parallel to a desired moving direction of the working fluid.

Furthermore, the amount of the working fluid which can be held by the protrusions 7 according to the present invention can be very readily and precisely controlled by adjusting an area of the bottom surface of the head portion 2, the height of the columnar portion 3, and the thickness of the columnar portion 3. A volume of a space occupied by the protrusions 7 in the vapor chamber 1 can be thus set to be the minimum volume for holding a required amount of working fluid, so that the thickness and the size of the vapor chamber 1 can be efficiently reduced. Further, a volume of a space occupied by the protrusions 7 in the vapor chamber 1 can be set to be the minimum volume for holding a required amount of working fluid, so that a volume of a space in which vapor of the working fluid, which is vaporized by heat from a heat source, moves can be kept large and transportation performance for heat of the vapor chamber 1 can be thus improved.

Each component of the vapor chamber 1 according to the present invention is described in detail below.

It is sufficient that the housing 10 of the vapor chamber 1 according to the present invention has two opposed main inner surfaces. The main inner surface of the housing 10 may have a polygonal shape or a circular shape. The main inner surface in the present specification represents a surface having the largest area and a surface opposed to the surface having the largest area among surfaces defining an inner space of the housing 10.

The housing 10 denoted by A in FIG. 1 (that is, the thickness of the vapor chamber 1) may be from 100 μm to 600 μm inclusive, and preferably in a range from 200 μm to 500 μm inclusive, for example. The width B of the housing 10 denoted by B in FIG. 1 (that is, the width of the vapor chamber 1) may be from 5 mm to 500 mm inclusive, preferably in a range from 20 mm to 300 mm inclusive, and further preferably in a range from 50 mm to 200 mm inclusive, for example. Further, though not illustrated, the depth D of the housing 10 which directs from the front side to the back side of the paper and intersects with the arrow denoting the width B of the housing 10 in FIG. 1 (that is, the depth of the vapor chamber 1) may be from 5 mm to 500 mm inclusive, preferably in a range from 20 mm to 300 mm inclusive, and further preferably in a range from 50 mm to 200 mm inclusive, for example. The above-mentioned height A, width B, and depth D may be even or vary on any parts of the housing 10.

The housing 10 may be integrally formed from a single member or may be composed of two opposed sheets with sealed outer peripheral portions, as illustrated in FIG. 1, for example. Further, the housing 10 may be composed of two or more plate-like members. In the vapor chamber 1 of FIG. 1, an upper housing sheet 8 forms an upper main inner surface of the housing 10 and a lower housing sheet 9 forms a lower main inner surface of the housing 10. In the housing 10, the upper housing sheet 8 and the lower housing sheet 9 are mutually sealed on respective outer peripheral portions thereof. The outer peripheral portions of the upper housing sheet 8 and the lower housing sheet 9 represent inner regions from end portions of the sheets by predetermined distance. In the vapor chamber 1 in FIG. 1, the outer peripheral portions of the upper housing sheet 8 and the lower housing sheet 9 are sealed by brazing. However, the method for sealing outer peripheral portions is not limited to this, and sealing may be performed by solder bonding, ultrasonic bonding, tungsten inert gas (TIG) welding, resin sealing, diffusion bonding, resistance welding, and laser welding, for example.

A material for forming the housing 10 is not especially limited. Cu, Ni, Ti, Mg, Al, Fe, and an alloy mainly containing these materials, for example, may be used as the material, and Cu and an Cu alloy are preferably used.

The thickness C of a wall surface which constitutes the housing 10 and is denoted by C in FIG. 1 (the thickness of the upper housing sheet 8 in the example illustrated in the drawing) may be from 10 μm to 200 μm inclusive, preferably in a range from 30 μm to 100 μm inclusive, further preferably in a range from 30 μm to 80 μm inclusive, and still further preferably in a range from 40 μm to 60 μm inclusive, for example. The above-mentioned thickness C may be even or vary on any parts of the housing 10. The thickness C of the upper housing sheet 8 and the thickness of the lower housing sheet 9 may be different from each other, for example.

Though not illustrated in FIG. 1, the working fluid is further sealed in the housing 10 of the vapor chamber 1 according to the present invention. The working fluid is vaporized by heat from a heating element so as to become vapor. After that, the vaporized working fluid moves inside the housing 10, discharges the heat, and returns to a liquid state. The working fluid which has returned to the liquid state is transferred to the vicinity of the heating element again by a capillary phenomenon. Then, the working fluid is vaporized again by heat from the heating element so as to become vapor. Through repetition of this process, the vapor chamber 1 according to the present invention can autonomously operate without requiring external power and two-dimensionally diffuse heat in a rapid way by using vaporization of the working fluid and latent heat of condensation.

The kind of working fluid is not especially limited. Water, alcohols, and alternative chlorofluorocarbon, for example, may be used, and water is preferably used. In the present invention, the working fluid moving among the lateral surfaces 5 and working fluid held in the space among the columnar portions 3 form mutually identical liquid phases. Therefore, the working fluid held in the space among the columnar portions 3 moves in the direction parallel to the lateral surfaces 5 along with movement of the working fluid among the lateral surfaces 5. Preferable a viscosity of the working fluid for thus allowing the working fluid held in the space among the columnar portions 3 to follow movement of the working fluid among the lateral surfaces 5 is from 0.1 mPa·s to 2 mPa·s inclusive, and preferably from 0.2 mPa·s to 1 mPa·s inclusive.

The housing 10 of the vapor chamber 1 according to the present invention is provided with a plurality of protrusions 7 on at least one main surface inside the housing 10. The protrusions 7 may be provided on the whole of one main surface as illustrated in FIG. 1 or may be partially provided.

The protrusion 7 is composed of the columnar portion 3 and the head portion 2. The columnar portion 3 of the protrusion 7 is formed in a columnar shape perpendicular to the main surface 6 of the housing 10. The columnar portion 3 of the protrusion 7 may have a substantially circular cylindrical shape as illustrated in FIG. 2, for example. Further, the columnar portion 3 of the protrusion 7 may have a substantially quadrangular prism shape as illustrated in FIG. 3, for example. Also, the columnar portion 3 of the protrusion 7 may have a truncated cone shape which is not illustrated. The columnar portions 3 of the protrusions 7 are separated from each other, as illustrated in FIG. 1. The vapor chamber 1 according to the present invention is capable of holding the working fluid in a space defined by a surface including wall surfaces of the columnar portions 3, the main surface 6 of the housing 10, and bottom surfaces of the head portions 2.

The columnar portion 3 may have the height of 1 μm to 100 μm inclusive, preferably in a range from 20 μm to 50 μm inclusive, further preferably in a range from 5 μm to 50 μm inclusive, and still further preferably in a range from 5 μm to 40 μm inclusive, for example. If the height of the columnar portion 3 is 1 μm or greater, the space among the columnar portions 3 for holding the working fluid can be sufficiently secured. Further, if the height of the columnar portion 3 is 100 μm or shorter, the working fluid held in the space among the columnar portions 3 can be more efficiently allowed to follow movement of the working fluid among the lateral surfaces 5.

The columnar portion 3 may have a thickness of 30 μm to 100 μm inclusive, preferably in a range from 30 μm to 60 μm inclusive, and further preferably in a range from 40 μm to 50 μm inclusive, for example. The thickness of the columnar portion 3 represents an equivalent circle diameter of a section of the columnar portion 3 on a surface parallel to the main surface 6 of the housing 10. The equivalent circle diameter of a section of the columnar portion 3 represents a diameter of a perfect circle having an area corresponding to an area of the section. If a cross section area of the columnar portion 3 is not constant, the equivalent circle diameter represents a diameter of a perfect circle having an area corresponding to an average value of cross section areas of the columnar portion 3. If the thickness of the columnar portion 3 is 30 μm or greater, the columnar portion 3 can support the head portion 2 with sufficient strength. Further, if the thickness of the columnar portion 3 is 100 μm or smaller, the space among the columnar portions 3 for holding the working fluid can be sufficiently secured.

The distance between the columnar portions 3 may be from 100 μm to 1000 μm inclusive, preferably in a range from 100 μm to 400 μm inclusive, and further preferably in a range from 150 μm to 250 μm inclusive, for example. If the distance between the columnar portions 3 is 100 μm or longer, the space among the columnar portions 3 for holding the working fluid can be sufficiently secured. Further, if the distance between the columnar portions 3 is 1000 μm or shorter, the working fluid held in the space among the columnar portions 3 can be more efficiently allowed to follow movement of the working fluid among the lateral surfaces 5.

The head portion 2 has two opposed surfaces and one or more lateral surfaces, and at least one lateral surface is opposed to a lateral surface of another head portion in a separate state as illustrated in FIG. 2 and FIG. 3. The vapor chamber 1 according to the present invention has such a structure, forming a gap between the lateral surface 5 of a head portion 2 and the lateral surface 5 of an adjacent head portion 2. Since the vapor chamber 1 according to the present invention has such a gap, the vapor chamber is capable of efficiently moving the working fluid by using capillary force. Further, the moving direction of the working fluid is parallel to the width direction of the lateral surface 5. Therefore, the moving direction of the working fluid can be easily controlled by providing head portions so that the width directions of part of lateral surfaces 5, preferably the width directions of two opposed lateral surfaces of a head portion are parallel to a desired moving direction of the working fluid.

In the vapor chamber 1 according to the present invention, the distance between the lateral surface 5 of a head portion 2 and the lateral surface 5 of another head portion 2 may be from 10 μm to 80 μm inclusive, and preferably in a range from 20 μm to 50 μm inclusive, for example. If the distance between the lateral surface 5 of a head portion 2 and the lateral surface 5 of another head portion 2 is in the above-mentioned range, the working fluid can be more efficiently moved by using capillary force. Further, it is preferable that the distance between the lateral surface 5 of any head portion 2 and the lateral surface 5 of other head portions 2 is constant among a plurality of protrusions 7. If the distance between the lateral surface 5 of a head portion 2 and the lateral surface 5 of another head portion 2 is constant, capillary force can evenly act in a region in which the protrusions 7 are formed, and a transport amount of the working fluid can be made even.

The head portion 2 is formed on the columnar portion 3 so that two opposed main surfaces thereof are parallel to the main surface 6 inside the housing 10, as illustrated in FIG. 2 and FIG. 3. In the present specification, the width of the head portion 2 represents the width of a section of the head portion 2, which exhibits the largest width of the head portion 2, among sections of the head portion 2 perpendicular to the main surface 6. The head portion 2 may have the width of 100 μm to 500 μm inclusive, and preferably in a range from 200 μm to 400 μm inclusive, for example.

A main surface 4 of the head portion 2 of the protrusion 7 preferably has a rectangular shape. More preferably, the head portion 2 of the protrusion 7 has a rectangular parallelepiped shape having the main surface 4 in a rectangular shape. Here, the main surface of the head portion represents a surface of a head portion (a surface of the head portion opposed to a surface having the columnar portion, in FIG. 1) opposed to a main surface, which is opposed to a main surface on which the protrusions are provided, of the housing 10. The main surface 4 of the head portion 2 may have a shape whose ratio of the length of a short side with respect to the length of a long side is approximately 1, as illustrated in FIG. 2. Further, a ratio of the length of a short side with respect to the length of a long side may be largely lower than 1, as illustrated in FIG. 3. Further, though not illustrated, a ratio of the length of a short side with respect to the length of a long side may be 1. That is, the main surface 4 of the head portion 2 may be square.

In the present invention, a long side of the head portion 2 may be from 100 μm to 500 μm inclusive in the length thereof, and preferably in a range from 200 μm to 400 μm inclusive in the length thereof, for example. Further, a short side of the head portion 2 may be from 100 μm to 500 μm inclusive in the length thereof, and preferably in a range from 200 μm to 400 μm inclusive in the length thereof, for example.

The height of the head portion 2 may be from 5 μm to 200 μm inclusive, and preferably in a range from 10 μm to 80 μm inclusive, for example. If the height of the head portion 2 is 5 μm or greater, sufficient quantity of working fluid can be moved by capillary force, being able to enhance transportation performance of the working fluid. If the height of the head portion 2 is 200 μm or shorter, pressure loss occurring when the working fluid moves between the upper side and the lower side of the head portion 2 can be lowered, and movement of the fluid can be thus facilitated.

The lateral surface 5 of the head portion 2 may be smooth as illustrated in FIG. 2 and FIG. 3. However, not limited to this, the lateral surface 5 may have an arbitrary shape. The lateral surface 5 of the head portion 2 may have concavities and convexities or bulges, for example.

The distance between the head portion 2 of a protrusion 7 and the head portion 2 of an adjacent protrusion 7 may be from 10 μm to 80 μm inclusive, preferably in a range from 20 μm to 50 μm inclusive, and further preferably in a range from 30 μm to 40 μm inclusive, for example. If the distance between the head portions 2 is 10 μm or longer, capillary force can act on sufficient quantity of working fluid. Further, the distance between the head portions 2 is 50 μm or shorter, capillary force can sufficiently act on the working fluid.

In the vapor chamber 1 according to the present invention, a first area of the head portion 2 measured in a direction perpendicular to the main surface 6 of the housing 10 is larger than a second area of the columnar portion 3. A percentage of the second area of the columnar portion 3 with respect to the first area of the head portion 2 may be from 10 to 99 inclusive, preferably in a range from 10 to 75 inclusive, and further preferably in a range from 25 to 75 inclusive, for example. If the percentage of the second area of the columnar portion 3 with respect to the first area of the head portion 2 is 10 or greater, the columnar portion 3 can support the head portion 2 with sufficient strength. If the percentage of the second area of the columnar portion 3 with respect to the first area of the head portion 2 is 75 or smaller, the space among the columnar portions 3 for holding the working fluid can be sufficiently secured.

A material for forming the protrusion 7 is not especially limited, and a photosensitive polymer such as a bisazido compound and a naphthoquinone diazide compound, for example, may be used. The head portion 2 and the columnar portion 3 of the protrusion 7 may be made of the same material or may be made of different materials. The protrusion 7 is preferably made of a material having high hydrophilicity. If a surface of the protrusion 7 is covered with a material having high hydrophilicity, hydrophilicity can be enhanced. A material for covering the protrusion 7 may be metal, for example, and Cu or the like is preferably used. If hydrophilicity of the protrusion 7 is enhanced, a holding force for the working fluid of the vapor chamber 1 according to the present invention can be enhanced and transportation performance for the working fluid can be enhanced.

FIGS. 1 to 3 illustrate the protrusion 7 composed of one columnar portion 3 and one head portion 2, but an aspect of the protrusion 7 is not limited to this. For example, a protrusion 7 may be used which is composed of two columnar portions 3 and two head portions 2 and is formed by vertically placing a set of the columnar portion 3 and the head portion 2, which are combined to have the shape illustrated in FIGS. 1 to 3, and another set so that axes of the columnar portions 3 are on the same straight line.

The protrusion 7 according to the present invention can be formed by a manufacturing method including the following steps i to v.

i: a step for forming a first-layer photoresist on a main surface inside a housing

ii: a step for exposing the first-layer photoresist in a pattern corresponding to columnar portions

iii: a step for forming a second-layer photoresist on the first-layer photoresist which is exposed

iv: a step for exposing the second-layer photoresist in a pattern corresponding to head portions

v: a step for developing the first-layer photoresist and the second-layer photoresist to obtain a resist pattern corresponding to protrusions

(i: A Step for Forming a First-Layer Photoresist on a Main Surface Inside a Housing)

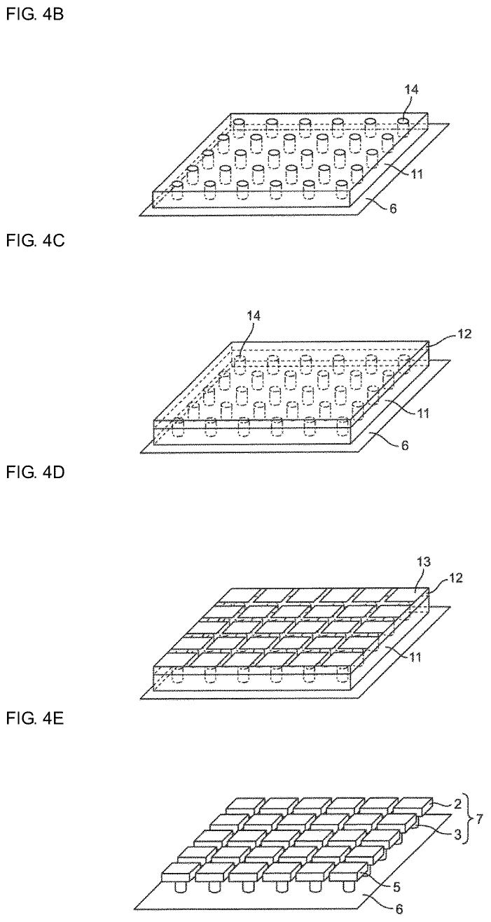

As illustrated in FIG. 4A, a first-layer photoresist 11 is formed on the main surface 6 inside the housing 10. The first-layer photoresist 11 can be formed by any method and can be formed by performing spin coating, for example. The first-layer photoresist 11 is used for forming the columnar portions 3 and the height of the first-layer photoresist 11 from the main surface 6 of the housing 10 is the height of the columnar portions 3. Photoresist liquid for forming the first-layer photoresist 11 is not especially limited and a naphthoquinone diazide compound, for example, can be used.

(ii: A Step for Exposing the First-Layer Photoresist in a Pattern Corresponding to Columnar Portions)

As illustrated in FIG. 4B, the first-layer photoresist 11 is exposed in a pattern corresponding to the columnar portions 3. Here, the pattern corresponding to the columnar portions 3 defines the area 14 of each of the columnar portions 3 in a direction perpendicular to the main surface 6 of the housing 10 in a use of negative type photoresist liquid. Further, in a use of positive type photoresist liquid, the pattern corresponds to a portion other than the area 14 of the columnar portions 3 in the direction perpendicular to the main surface 6 of the housing 10. Exposure of the first-layer photoresist 11 in a pattern corresponding to the columnar portions 3 may be attained by masking and irradiating with ultraviolet light from the top when a positive type photoresist liquid is used, for example. FIG. 4B shows unexposed regions in the inside of the first-layer photoresist 11 with a chain double-dashed line.

(iii: A Step for Forming a Second-Layer Photoresist on the First-Layer Photoresist which is Exposed)

As illustrated in FIG. 4C, a second-layer photoresist 12 is formed on the first-layer photoresist 11. The second-layer photoresist 12 can be formed by any method and can be formed by performing spin coating, for example. The second-layer photoresist 12 is used for forming the head portions 2 and the height of the second-layer photoresist 12 from the upper surface of the first-layer photoresist 11 is the height of the head portions 2. Photoresist liquid for forming the second-layer photoresist 12 is not especially limited and a naphthoquinone diazide compound, for example, can be used.

(iv: A Step for Exposing the Second-Layer Photoresist in a Pattern Corresponding to Head Portions)

As illustrated in FIG. 4D, the second-layer photoresist 12 is exposed in a pattern corresponding to the head portions 2. Here, the pattern corresponding to the head portions 2 defines the area 13 of each of the head portions 2 in a direction perpendicular to the main surface 6 of the housing 10, in a use of negative type photoresist liquid. Further, in a use of positive type photoresist liquid, the pattern corresponds to a portion other than the area 13 for each of the head portions 2 in the direction perpendicular to the main surface 6 of the housing 10. Exposure of the second-layer photoresist 12 in a pattern corresponding to the head portions 2 may be attained by masking and irradiating with ultraviolet light from the top when a positive type photoresist liquid is used, for example.

(v: A Step for Developing the First-Layer Photoresist and the Second-Layer Photoresist to Obtain a Resist Pattern Corresponding to Protrusions)

As illustrated in FIG. 4E, the first-layer photoresist 11 and the second-layer photoresist 12 are developed to obtain a resist pattern corresponding to the protrusions 7. Developer used in this step may be developer by which the first-layer photoresist 11 and the second-layer photoresist 12 can be developed and alkaline solution or tetramethylammonium hydroxide (TMAH), for example, may be used.

As described above, protrusions of the vapor chamber according to the present invention are formed by the above-described manufacturing method. That is, the vapor chamber according to the present invention can be manufactured by a method including the above-described manufacturing method.

By manufacturing the protrusions 7 according to the present invention by the above-described method, desired dimensions can be reproduced with significantly high accuracy. The protrusions 7 according to the present invention can be manufactured by a 3D printer, for example, as well as the above-described method.

The vapor chamber according to the present invention can be mounted in or on a heat dissipation device in a manner to be close to a heat source. Accordingly, the present invention also provides a heat dissipation device including the vapor chamber according to the present invention. If the heat dissipation device of the present invention includes the vapor chamber according to the present invention, temperature of an electronic component generating heat and temperature around the component can be efficiently depressed.

The vapor chamber or the heat dissipation device according to the present invention can be mounted in or on an electronic device for heat dissipation. Accordingly, the present invention provides an electronic device including the vapor chamber or the heat dissipation device according to the present invention. Examples of the electronic device according to the present invention include a smartphone, a tablet, and a laptop. The vapor chamber according to the present invention can autonomously operate without requiring external power and two-dimensionally diffuse heat at high speed by using vaporization of working fluid and latent heat of condensation, as described above. Accordingly, if an electronic device includes the vapor chamber or heat dissipation device according to the present invention, heat dissipation can be efficiently realized in a limited space in the electronic device.

The vapor chamber, heat dissipation device, and electronic device according to the present invention can be used in a wide range of applications in the field of a portable information terminal. For example, since the vapor chamber, heat dissipation device, and electronic device lower temperature of a heat source of a CPU or the like, these can be used to elongate use time of a portable information terminal and can be used in a smartphone, a tablet, a laptop, and the like.

### REFERENCE SIGNS LIST

1 vapor chamber
2 head portion
3 columnar portion
4 main surface of head portion
5 lateral surface of head portion
6 main surface of housing
7 protrusion
8 upper housing sheet
9 lower housing sheet
10 housing
11 first-layer photoresist
12 second-layer photoresist
13 area of head portion
14 area of columnar portion

1. A vapor chamber comprising:
a housing;
a plurality of protrusions on at least one main surface inside the housing, each of the plurality of protrusions having a columnar portion and a head portion, lateral surfaces of the head portions of adjacent protrusions of the plurality of protrusions face each other, and a first area of the head portion is larger than a second area of the columnar portion when measured in a direction perpendicular to the main surface of the housing; and
a working fluid sealed in the housing.

2. The vapor chamber according to claim 1, wherein the head portion has a rectangular shape when viewed from a direction perpendicular to the main surface of the housing.

3. The vapor chamber according to claim 1, wherein the head portion has a square shape when viewed from a direction perpendicular to the main surface of the housing.

4. The vapor chamber according to claim 1, wherein the head portion has a width of 100 μm to 500 μm inclusive.

5. The vapor chamber according to claim 1, wherein a distance between the head portions of the adjacent protrusions of the plurality of protrusions is from 10 μm to 80 μm inclusive.

6. The vapor chamber according to claim 1, wherein a distance between the head portions of the adjacent protrusions of the plurality of protrusions is constant.

7. The vapor chamber according to claim 1, wherein the columnar portion has a height of 1 μm to 100 μm inclusive.

8. The vapor chamber according to claim 1, wherein the plurality of protrusion are covered with metal.

9. The vapor chamber according to claim 8, wherein the metal is Cu.

10. The vapor chamber according to claim 1, wherein the columnar portion has a circular cylindrical shape.

11. The vapor chamber according to claim 1, wherein the columnar portion has a quadrangular prism shape.

12. The vapor chamber according to claim 1, wherein a distance between adjacent columnar portions of the plurality of protrusions is from 100 μm to 1000 μm inclusive.

13. A manufacturing method for a vapor chamber, the method comprising:
forming a first-layer photoresist on a main surface inside of a housing;
exposing the first-layer photoresist in a pattern corresponding to a plurality of columnar portions;
forming a second-layer photoresist on the exposed first-layer photoresist;
exposing the second-layer photoresist in a pattern corresponding to a plurality of head portions; and
developing the first-layer photoresist and the second-layer photoresist to obtain a resist pattern with a plurality of protrusions each of which having a respective columnar portion and head portion, and such that lateral surfaces of the head portions of adjacent protrusions of the plurality of protrusions face each other, and a first area of a head portion of the plurality of head portions is larger than a second area of a columnar portion of the plurality of columnar portions when measured in a direction perpendicular to the main surface of the housing.

14. The method of manufacturing a vapor chamber according to claim 13, wherein a distance between the head portions of the adjacent protrusions of the plurality of protrusions is from 10 μm to 80 μm inclusive.

15. The method of manufacturing a vapor chamber according to claim 13, wherein a distance between the head portions of the adjacent protrusions of the plurality of protrusions is constant.

16. The method of manufacturing a vapor chamber according to claim 13, wherein the columnar portion has a height of 1 μm to 100 μm inclusive.

17. The method of manufacturing a vapor chamber according to claim 13, further comprising covering the plurality of protrusion with metal.

18. The method of manufacturing a vapor chamber according to claim 17, wherein the metal is Cu.

19. The method of manufacturing a vapor chamber according to claim 13, wherein a distance between adjacent columnar portions of the plurality of protrusions is from 100 μm to 1000 μm inclusive.

20. A manufacturing method for a vapor chamber, the method comprising:
3D printing a plurality of protrusions on a main surface inside of a housing such that each of the plurality of protrusions includes a respective columnar portion and head portion, and such that lateral surfaces of the head portions of adjacent protrusions of the plurality of protrusions face each other, and a first area of the head portion is larger than a second area of the columnar portion when measured in a direction perpendicular to the main surface of the housing.
